(19) United States
(12) Patent Application Publication
(10) Pub. No.: US 2026/0076085 A1
(43) Pub. Date: Mar. 12, 2026

(54) SENSOR AND DETECTION DEVICE

(71) Applicant: Japan Display Inc., Tokyo (JP)

(72) Inventor: Mamoru DOUYOU, Tokyo (JP)

(73) Assignee: Japan Display Inc., Tokyo (JP)

(21) Appl. No.: 19/318,430

(22) Filed: Sep. 4, 2025

(30) Foreign Application Priority Data
Sep. 6, 2024 (JP) 2024-154051

(51) Int. Cl. H10K 65/00; H10K 30/82; H10K 30/86; H10K 30/89

(52) U.S. Cl. CPC H10K 65/00; H10K 30/82; H10K 30/86; H10K 30/89

(57) ABSTRACT

According to one embodiment, a sensor includes an insulating substrate including a first island portion and a second island portion arranged in a first direction and a band portion provided between the first island portion and the second island portion to connect the first island portion with the second island portion, an insulating layer provided above the insulating substrate, a plurality of first electrodes provided on the insulating layer to overlap with each of the first island portion and the second island portion in plan view, and a semiconductor layer provided on the plurality of first electrodes. The band portion is curved.

### CROSS-REFERENCE TO RELATED APPLICATION

This application is based upon and claims the benefit of priority from Japanese Patent Application No. 2024-154051, filed Sep. 6, 2024, the entire contents of which are incorporated herein by reference.

### FIELD

Embodiments described herein relate generally to a sensor and a detection device.

### BACKGROUND

Optical sensors capable of detecting fingerprint patterns or vein patterns are known. Such optical sensors are sometimes incorporated into a ring-shaped housing to form a ring-shaped detection device. In such sensors, there is a need for a sensor which can be applied to housings of various sizes.

### BRIEF DESCRIPTION OF THE DRAWINGS

FIG. 1 is a schematic diagram showing a configuration example in which a state of inserting a finger into a detection device of the present embodiment is viewed from a side of a housing.

FIG. 2 is a schematic cross-sectional view showing the detection device along II-II line in FIG. 1.

FIG. 3 is a plan view showing a configuration example of a sensor of the present embodiment.

FIG. 4 is a schematic cross-sectional view showing the sensor along IV-IV line in FIG. 3.

FIG. 5 is a cross-sectional view showing a configuration example of the detection device shown in FIG. 2.

FIG. 6 is a plan view showing a state in which a band portion of the sensor shown in FIG. 3 extends in a first direction.

FIG. 7 is a plan view showing a sensor of a comparative example.

FIG. 8 is a plan view showing another configuration example of the sensor shown in FIG. 3.

FIG. 9 is a plan view showing another configuration example of the sensor shown in FIG. 8.

FIG. 10 is a plan view showing another configuration example of the sensor shown in FIG. 3.

FIG. 11 is a schematic cross-sectional view showing the sensor along XI-XI line in FIG. 10.

### DETAILED DESCRIPTION

In general, according to one embodiment, a sensor includes: an insulating substrate including a first island portion and a second island portion arranged in a first direction, and a band portion provided between the first island portion and the second island portion to connect the first island portion with the second island portion; an insulating layer provided above the insulating substrate; a plurality of first electrodes provided on the insulating layer to overlap with each of the first island portion and the second island portion in plan view; and a semiconductor layer provided on the plurality of first electrodes. The band portion is curved.

According to another embodiment, a detection device includes a sensor and a ring-shaped housing. The sensor comprises an insulating substrate including a first island portion and a second island portion arranged in a first direction a band portion provided between the first island portion and the second island portion to connect the first island portion with the second island portion, an insulating layer provided above the insulating substrate, a plurality of first electrodes provided on the insulating layer to overlap with each of the first island portion and the second island portion in plan view, and a semiconductor layer provided on the plurality of first electrodes. The band portion is curved, and the sensor is provided inside the housing.

According to yet another embodiment, a detection device includes a sensor and a ring-shaped housing. The sensor comprises an insulating substrate including a first island portion and a second island portion arranged in a first direction and a band portion provided between the first island portion and the second island portion to connect the first island portion with the second island portion, an insulating layer provided above the insulating substrate, a plurality of first electrodes provided on the insulating layer to overlap with each of the first island portion and the second island portion in plan view, a semiconductor layer provided on the plurality of first electrodes, a first light source provided between the first island portion and the second island portion in plan view, a second light source provided between the first island portion and the first light source in the first direction, and a third light source provided between the second island portion and the first light source in the first direction. The band portion is curved, and the sensor is provided inside the housing.

According to these configurations, the sensor which can be applied to housings of various sizes can be provided.

Embodiments will be described hereinafter with reference to the accompanying drawings. The disclosure is merely an example, and proper changes within the spirit of the invention, which are easily conceivable by a person of ordinary skill in the art, are included in the scope of the invention as a matter of course. In addition, in some cases, in order to make the description clearer, the widths, thicknesses, shapes and the like, of the respective parts are schematically illustrated in the drawings, compared to the actual modes. However, the schematic illustration is merely an example, and adds no restriction to the interpretation of the invention. In addition, in the specification and drawings, structural elements which function in the same or a similar manner to those described in connection with preceding drawings are denoted by like reference numbers, detailed description thereof being omitted unless necessary.

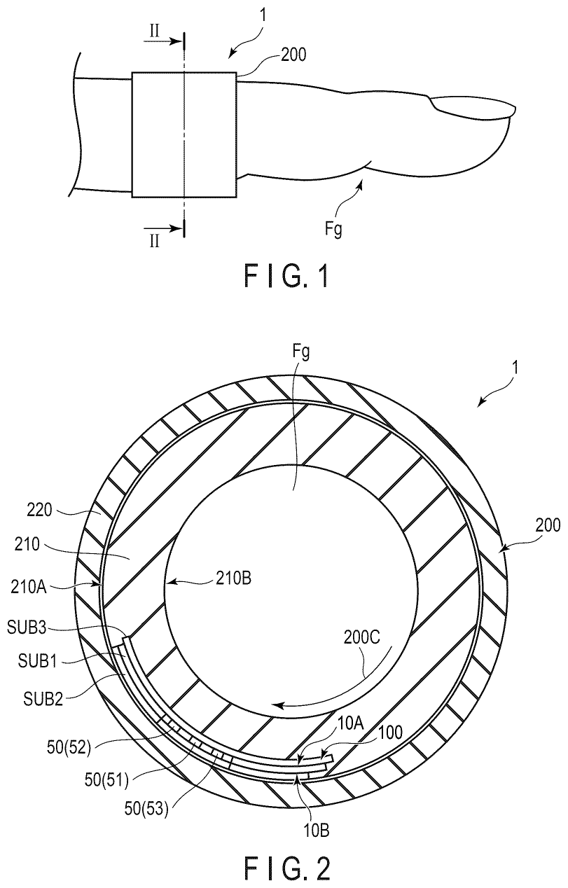

FIG. 1 is a schematic diagram showing a configuration example in which a state of inserting a finger Fg into a detection device 1 of the present embodiment is viewed from a side of a housing 200.

The detection device 1 shown in FIG. 1 is a ring-shaped device that can be attached to and detached from a detected object such as a human body. In the example shown in FIG. 1, the detection device 1 is attached to a finger Fg of the human body, but may also be attached to a wrist, an ankle or the like of the human body. The finger Fg implies a thumb, an index finger, a middle finger, a ring finger, a little finger and the like. The detection device 1 can detect information on a living body of the subject, i.e., biometric information from the finger Fg or the like to which the detection device 1 is attached.

FIG. 2 is a schematic cross-sectional view showing the detection device 1 along II-II line in FIG. 1.

As shown in FIG. 2, the detection device 1 comprises a sensor 100 and a ring-shaped housing 200. The detection device 1 further comprises a battery (not shown) inside the housing 200. The detection device 1 operates using power from the battery.

In the example shown in FIG. 2, the housing 200 comprises a first housing 210 and a second housing 220. The first housing 210 has a ring shape and includes an outer circumferential surface 210A and an inner circumferential surface 210B. The first housing 210 comes into contact with an object to be detected, for example, a finger Fg, via its inner circumferential surface 210B. The second housing 220 covers the outer circumferential surface 210A of the first housing 210. The housing 200 accommodates the sensor 100 inside the first housing 210.

The first housing 210 is formed of, for example, a material such as light-transmissive synthetic resin or silicon. The second housing 220 is formed of, for example, a material such as metal or non-transmissive synthetic resin.

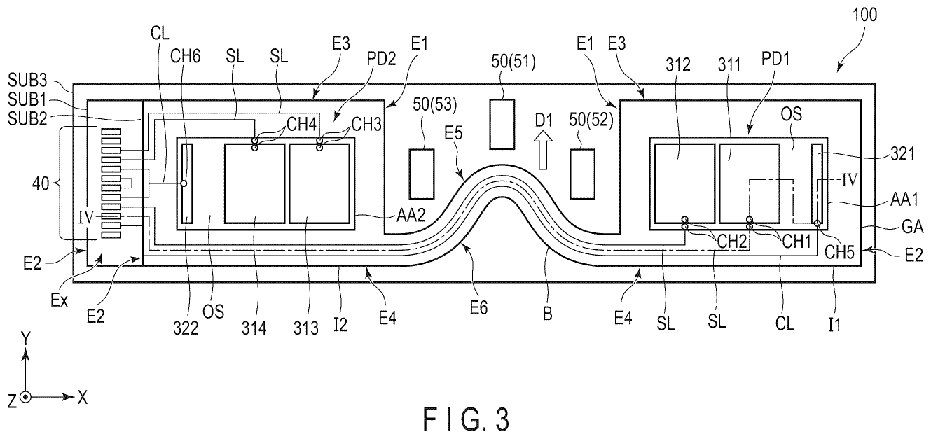

FIG. 3 is a plan view showing a configuration example of the sensor 100 of the present embodiment. In one example, the first direction X, the second direction Y, and the third direction Z are orthogonal to each other, but may intersect at an angle other than ninety degrees. The first direction X and the second direction Y correspond to the directions parallel to the surface of a substrate which constitutes the sensor 100, and the third direction Z corresponds to the thickness direction of the sensor 100. As described herein, a direction from the first substrate SUB1 toward the second substrate SUB2 is referred to as an upper side (or merely above), and a direction from the second substrate SUB2 toward the first substrate SUB1 is referred to as a lower side (or merely below).

According to “a second member above/on a first member” and “a second member below/under a first member”, the second member may be in contact with the first member or may be separated from the first member. In addition, an observation position at which the sensor 100 is to be observed is assumed to be located on the tip side of the arrow indicating the third direction Z, and viewing from the observation position toward an X-Y plane defined by the first direction X and the second direction Y is referred to as plan view.

Incidentally, FIG. 3 shows a first photodiode PD1, a second photodiode PD2, a plurality of signal lines SL, power supply lines CL1 and CL2 through the second substrate SUB2.

The sensor 100 comprises the first substrate SUB1 and the second substrate SUB2. The first substrate SUB1 and the second substrate SUB2 are formed in a flat plate shape parallel to the X-Y plane. For example, the first substrate SUB1 and the second substrate SUB2 is may be bent.

The first substrate SUB1 includes a first island portion I1, a second island portion I2, and a band portion B which is provided between the first island portion I1 and the second island portion I2 to connect the first island portion I1 with the second island portion I2.

In the example shown in FIG. 3, each of the first island portion I1 and the second island portion I2 of the first substrate SUB1 has a substantially rectangular shape. Each of the first island portion I1 and the second island portion I2 of the first substrate SUB1 extends along the second direction Y and has edges E1 and E2 that face each other. The edge E1 of the first island portion I1 faces the edge E1 of the second island portion I2 in the first direction X.

In addition, in the example shown in FIG. 3, each of the first island portion I1 and the second island portion I2 of the first substrate SUB1 extends along the first direction X and has edges E3 and E4 that face each other. The edge E3 is located on a side of a protruding direction D1 of the band portion B, which will be described later, relative to the edge E4, in the second direction Y.

The band portion B of the first substrate SUB1 is curved in the X-Y plane. In the example shown in FIG. 3, the band portion B is curved to protrude in the direction from the edge E4 toward the edge E3, i.e., in the D1 direction shown in FIG. 3, in the second direction Y. In the example shown in FIG. 3, the band portion B comprises one portion protruding in the D1 direction, which is not particularly limited, but may comprise one or more portions protruding in the D1 direction.

In the example shown in FIG. 3, the band portion B of the first substrate SUB1 has edges E5 and E6 that face each other in the second direction Y. The edge E5 is located on the edge E3 side relative to the edge E6 in the second direction Y. In other words, the edge E5 is located on the side of the protruding direction D1 of the band portion B, relative to the edge E6, in the second direction Y. Each of the edges E5 and E6 has a curved edge in the curved portion.

The band portion B of the first substrate SUB1 connects the first island portion I1 and the second island portion I2 of the first substrate SUB1.

In the example shown in FIG. 3, one end portion of the band portion B is connected to the edge E1 of the first island portion I1. In addition, the other end portion of the band portion B is connected to the edge E1 of the second island portion I2. More specifically, the connection portion between one end portion of the band portion B and the first island portion I1 is close to the edge E4 side in the second direction Y. In addition, the connection portion between the other end portion of the band portion B and the second island portion I2 is close to the edge E4 side in the second direction Y. In the example shown in FIG. 3, the edge E6 is continuously connected to the edge E4 of the first island portion I1 and the edge E4 of the second island portion I2.

The second substrate SUB2 includes a first island portion I1, a second island portion I2, and a band portion B which is provided between the first island portion I1 and the second island portion I2 to connect the first island portion I1 with the second island portion I2.

In the example shown in FIG. 3, each of the first island portion I1 and the second island portion I2 of the second substrate SUB2 has a substantially rectangular shape. Each of the first island portion I1 and the second island portion I2 of the second substrate SUB2 extends along the second direction Y and has edges E1 and E2 that face each other. The edge E1 of the first island portion I1 faces the edge E1 of the second island portion I2 in the first direction X.

In addition, in the example shown in FIG. 3, each of the first island portion I1 and the second island portion I2 of the second substrate SUB2 extends along the first direction X and has edges E3 and E4 that face each other. The edge E3 is located on the side of the protruding direction D1 of the band portion B, relative to the edge E4, in the second direction Y.

The band portion B of the second substrate SUB2 is curved in the X-Y plane. In the example shown in FIG. 3, the band portion B is curved by protruding in the second direction Y. In other words, the band portion B is curved to protrude in the direction from the edge E4 toward the edge E3, i.e., in the D1 direction shown in FIG. 3. In the example shown in FIG. 3, the band portion B comprises one portion protruding in the D1 direction, which is not particularly limited, but may comprise one or more portions protruding in the D1 direction.

In the example shown in FIG. 3, the band portion B of the second substrate SUB2 has edges E5 and E6 that face each other in the second direction Y. The edge E5 is located on the edge E3 side relative to the edge E6 in the second direction Y. In other words, the edge E5 is located on the side of the protruding direction D1 of the band portion B, relative to the edge E6, in the second direction Y. Each of the edges E5 and E6 has a curved edge in the curved portion.

The band portion B of the second substrate SUB2 connects the first island portion I1 and the second island portion I2 of the second substrate SUB2. In the example shown in FIG. 3, one end portion of the band portion B is connected to the edge E1 of the first island portion I1. In addition, the other end portion of the band portion B is connected to the edge E1 of the second island portion I2. More specifically, the connection portion between one end portion of the band portion B and the first island portion I1 is close to the edge E4 side in the second direction Y. In addition, the connection portion between the other end portion of the band portion B and the second island portion I2 is close to the edge E4 side in the second direction Y. In the example shown in FIG. 3, the edge E6 is continuously connected to the edge E4 of the first island portion I1 and the edge E4 of the second island portion I2.

The first substrate SUB1 and the second substrate SUB2 overlap with each other in plan view. The edges E1 of the first substrate SUB1 and the second substrate SUB2 overlap with each other in plan view. The edges E3 of the first substrate SUB1 and the second substrate SUB2 overlap with each other in plan view. The edges E4 of the first substrate SUB1 and the second substrate SUB2 overlap with each other in plan view. The edges E5 of the first substrate SUB1 and the second substrate SUB2 overlap with each other in plan view. The edges E6 of the first substrate SUB1 and the second substrate SUB2 overlap with each other in plan view.

The second island portion I2 of the first substrate SUB1 comprises an extending portion Ex that extends in the first direction X in plan view. The extending portion Ex does not overlap with the second substrate SUB2 in plan view. In other words, the edges E2 of the first substrate SUB1 and the second substrate SUB2 do not overlap with each other in plan view.

In other words, the sensor 100 includes the first island portion I1, the second island portion I2, and the band portion B which is provided between the first island portion I1 and the second island portion I2 to connect the first island portion I1 with the second island portion I2, in the area where the first substrate SUB1 and the second substrate SUB2 overlap, in plan view. In the example shown in FIG. 3, each of the first island portion I1 and the second island portion I2 of the sensor 100 extends along the second direction Y and has edges E1 and E2 that face each other. In addition, each of the first island portion I1 and the second island portion I2 of the sensor 100 extends along the first direction X and has edges E3 and E4 that face each other.

The sensor 100 may further comprise a third substrate SUB3. The third substrate SUB3 is formed in a flat plate shape parallel to the X-Y plane. The third substrate SUB3 has, for example, a rectangular shape. The first substrate SUB1 and the second substrate SUB2 overlap with the third substrate SUB3 in plan view.

The sensor 100 comprises two detection areas AA1 and AA2 and a surrounding area GA in the area where the first substrate SUB1 and the second substrate SUB2 overlap. In the example shown in FIG. 3, the detection area AA1 overlaps with the first island portion I1 in plan view, and the other detection area AA2 overlaps with the second island portion I2 in a plan view. The surrounding area GA surrounds the detection areas AA1 and AA2. In addition, the surrounding area GA overlaps with the band portion B in plan view. The detection area AA1 includes the first photodiode PD1, and the detection area AA2 includes the second photodiode PD2.

The first photodiode PD1 and the second photodiode PD2 output electrical signals corresponding to the light made incident on the respective photodiodes. The first photodiode PD1 and the second photodiode PD2 are, for example, organic photodiodes (OPD) using organic semiconductors.

Each of the first photodiode PD1 and the second photodiode PD2 includes a semiconductor layer, a first electrode 31, and a second electrode 32. In the example shown in FIG. 3, the first photodiode PD1 includes an organic semiconductor layer OS, first electrodes 311 and 312, and a second electrode 321. The first electrodes 312 and 311 and the second electrodes 321 are arranged in this order in the first direction X. The organic semiconductor layer OS of the first photodiode PD1 overlaps with the first electrodes 311 and 312 and the second electrode 321 in plan view, and is provided across the first electrodes 311 and 312 and the second electrode 321. The organic semiconductor layer OS of the first photodiode PD1 overlaps with the detection area AA1 in plan view.

In the example shown in FIG. 3, the second photodiode PD2 includes an organic semiconductor layer OS, first electrodes 313 and 314, and a second electrode 322. The second electrode 322 and the first electrodes 314 and 313 are arranged in this order in the first direction X. The organic semiconductor layer OS of the second photodiode PD2 overlaps with the first electrodes 313 and 314 and the second electrode 322 in plan view, and is provided across the first electrodes 313 and 314 and the second electrode 322. The organic semiconductor layer OS of the second photodiode PD2 overlaps with the detection area AA2 in plan view.

The sensor 100 further comprises a plurality of terminals 40. The plurality of terminals 40 are provided at the extending portion Ex of the first substrate SUB1. In the example shown in FIG. 3, the plurality of terminals 40 are arranged in the second direction Y. Each of the plurality of terminals 40 is connected to a control circuit (not shown).

The first electrode 31 is electrically connected to the signal line SL. In the example shown in FIG. 3, the first electrodes 311, 312, 313, and 314 are connected to the signal lines SL via contact holes (CH1, CH2, CH3, and CH4) formed in the insulating layer 13 which will be described below, respectively.

The signal line SL connected to the first electrode 311 extends in the second direction Y from the connection point (contact hole CH1) with the first electrode 311, bends in the first direction X, and extends in the first direction X. The signal line SL connected to the first electrode 312 extends in the second direction Y from the connection point (contact hole CH2) with the first electrode 312, bends in the first direction X, and extends in the first direction X. Each of the signal lines SL connected to the first electrodes 311 and 312 overlaps with the band portion B in plan view.

The signal line SL connected to the first electrode 313 extends in the second direction Y from the connection point (contact hole CH3) with the first electrode 313, bends in the first direction X, and extends in the first direction X. The signal line SL connected to the first electrode 314 extends in the second direction Y from the connection point (contact hole CH4) with the first electrode 314, bends in the first direction X, and extends in the first direction X. Each of the signal lines SL connected to the first electrodes 313 and 314 does not overlap with the band portion B in plan view.

The signal line SL is connected to one of the plurality of terminals 40. In other words, each of the first electrodes 311, 312, 313, and 314 is connected to the control circuit via the signal line SL and the terminal 40.

The second electrode 32 is electrically connected to a power supply line CL. In the example shown in FIG. 3, the second electrodes 321 and 322 are connected to the power supply lines CL via contact holes CH5 and CH6 formed in the insulating layer 13 which will be described below, respectively.

The power supply line CL connected to the second electrode 321 extends in the second direction Y from the connection point (contact hole CH5) with the second electrode 321, bends in the first direction X, and extends in the first direction X. The power supply line CL connected to the second electrode 321 overlaps with the band portion B in plan view.

The power supply line CL connected to the second electrode 322 extends in the second direction Y from the connection point (contact hole CH6) with the second electrode 322. The power supply line CL connected to the second electrode 322 does not overlap with the band portion B in plan view.

The power supply line CL is connected to one of the plurality of terminals 40. In other words, each of the second electrodes 321 and 322 is connected to the control circuit via the power supply line CL and the terminal 40.

The signal lines SL and the power supply lines CL overlap with the surrounding area GA in plan view. The signal lines SL and the power supply lines CL are provided on the same layer.

The control circuit supplies control signals to the first photodiode PD1 and the second photodiode PD2 to control the detection operation. The first photodiode PD1 and the second photodiode PD2 output electrical signals corresponding to the light applied to the photodiodes as detection signals, respectively, to the control circuit. The detection device 1 detects information related to the detected object based on the detection signals.

The sensor 100 further comprises light sources 50. In the example shown in FIG. 3, the sensor 100 comprises three light sources 50, i.e., a first light source 51, a second light source 52, and a third light source 53.

The first light source 51 is provided between the first island portion I1 and the second island portion I2 in plan view. The second light source 52 is provided between the first island portion I1 and the first light source 51 in the first direction X. It can also be considered that the second light source 52 is provided between the curved portion of the band portion B and the first island portion I1 in the first direction X. The third light source 53 is provided between the second island portion I2 and the first light source 51 in the first direction X. It can also be considered that the third light source 53 is provided between the curved portion of the band portion B and the second island portion I2 in the first direction X. The first light source 51 is provided to protrude in the same direction as the protruding direction D1 of the band portion B in the second direction Y, relative to the second light source 52 and the third light source 53.

The light sources 50 do not overlap with first substrate SUB1 and second substrate SUB2 in plan view. When the sensor 100 comprises the third substrate SUB3, the light sources 50 may be provided on the third substrate SUB3.

For example, inorganic light emitting diodes (LED), organic EL (OLED: organic light emitting diodes) or the like are used as the light sources 50. For example, the first light source 51 emits infrared light or red light, and the second light source 52 and the third light source 53 emit green light.

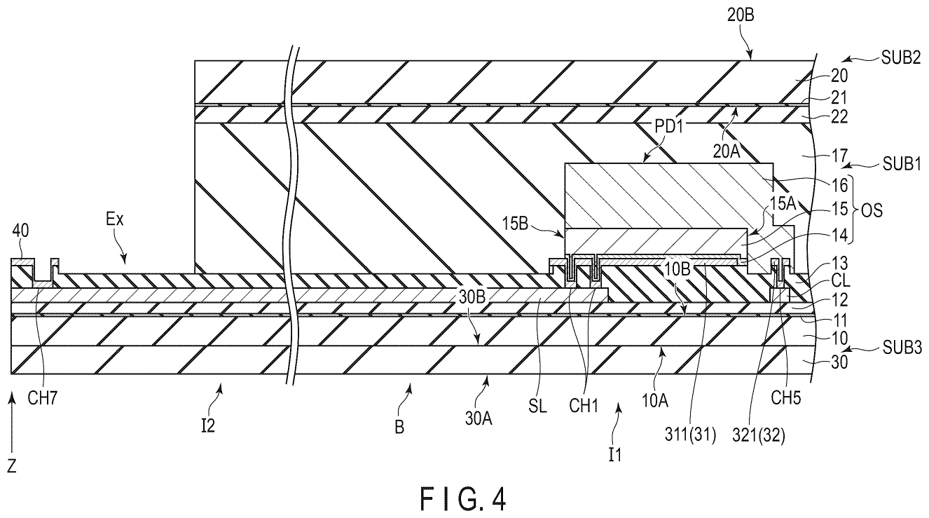

FIG. 4 is a schematic cross-sectional view showing the sensor 100 along IV-IV line in FIG. 3.

This figure mainly shows the first island portion I1, the band portion B, and the extending portion Ex of the sensor 100.

The first substrate SUB1 comprises an insulating substrate 10, a protective layer 11, a buffer layer 12, an insulating layer 13, a first photodiode PD1, a second photodiode PD2, a sealing adhesive layer 17, a signal line SL, a power supply line CL, and a terminal 40.

The insulating substrate 10 has a main surface (lower surface) 10A and a main surface (upper surface) 10B on a side opposite to the main surface 10A. The protective layer 11 covers the main surface 10B across the first island portion I1, the second island portion I2, and the band portion B. The buffer layer 12 covers the protective layer 11. Each of the signal line SL and the power supply line CL is provided on the buffer layer 12.

The insulating layer 13 covers the buffer layer 12, the signal line SL, and the power supply line CL. The first photodiode PD1 is provided on the insulating layer 13 overlapping with the first island portion I1, in plan view. Although not shown, the second photodiode PD2 is provided on the insulating layer 13 overlapping with the second island portion I2, in plan view.

The first photodiode PD1 comprises the first electrodes 311 and 312, the second electrode 321, and the organic semiconductor layer OS. In FIG. 4, illustration of the first electrode 312 is omitted.

The second photodiode PD2 comprises the first electrodes 313 and 314, the second electrode 322, and the organic semiconductor layer OS.

The first electrodes 311 and 312 and the second electrode 321 are provided on the insulating layer 13. Although not shown, the first electrodes 313 and 314 and the second electrode 322 are also provided on the insulating layer 13. In addition, the terminal 40 is provided on the insulating layer 13 overlapping with the extending portion Ex, in plan view.

The first electrode 311 is electrically connected to the signal line SL through the contact hole (CH1) formed in the insulating layer 13. Although not shown, each of the first electrodes 312, 313, and 314 is also electrically connected to the signal line SL via the contact hole (CH2, CH3, or CH4) formed in the insulating layer 13.

The second electrode 321 is electrically connected to the power supply line CL through the contact hole (CH5) formed in the insulating layer 13.

Although not shown, the second electrode 322 is also electrically connected to the power supply line CL via the contact hole (CH6) formed in the insulating layer 13.

The terminal 40 is electrically connected to the signal line SL through the contact hole (CH7) formed in the insulating layer 13.

The organic semiconductor layer OS overlapping with the first island portion I1 covers the first electrodes 311 and 312 and the second electrode 321, in plan view. Although not shown, the organic semiconductor layer OS overlapping with the second island portion I2 covers the first electrodes 313 and 314 and the second electrode 322, in plan view. The organic semiconductor layer OS includes an electron injection layer 14, an active layer 15, and a hole injection layer 16, as shown in FIG. 4.

The electron injection layer 14 overlapping with the first island portion I1 continuously covers the first electrodes 311 and 312, in plan view.

Although not shown, the electron injection layer 14 overlapping with the second island portion I2 covers the first electrodes 313 and 314, in plan view.

Incidentally, as shown in FIG. 4, a part of the first electrode 31 may be exposed from the electron injection layer 14.

The active layer 15 covers an upper surface of the electron injection layer 14. The hole injection layer 16 continuously covers an upper surface and a side surface 15A which faces the second electrode 32, of the active layer 15, and the second electrode 32.

The hole injection layer 16 is in contact with the second electrode 32. As shown in FIG. 4, the side surface 15B of the electron injection layer 14 that does not face the second electrode 32 may be exposed from the hole injection layer 16.

The sealing adhesive layer 17 is provided across the first island portion I1, the second island portion I2, and the band portion B. The sealing adhesive layer 17 covers the insulating layer 13, the hole injection layer 16, the side surface 15B of the active layer 15, and the first electrode 31 exposed from the active layer 15. By forming the sealing adhesive layer 17, the photodiode PD is desirably sealed, and intrusion of moisture from the upper surface can be thereby suppressed.

The sealing adhesive layer 17 is not provided on the extending portion Ex. In other words, at the extending portion Ex, the insulating layer 13, the contact hole CH7, and the terminal 40 are exposed from the sealing adhesive layer 17.

The second substrate SUB2 includes an insulating substrate 20, a protective layer 21, and a buffer layer 22. The insulating substrate 20 has a main surface (lower surface) 20A and a main surface (upper surface) 20B on a side opposite to the main surface 20A. The protective layer 21 covers the main surface 20A. The buffer layer 22 covers the protective layer 21. The protective layer 21 is bonded to the first substrate SUB1 by the sealing adhesive layer 17. The first substrate SUB1 and the second substrate SUB2 are thereby bonded to each other.

The third substrate SUB3 comprises an insulating substrate 30. The insulating substrate 30 has a main surface (lower surface) 30A and a main surface (upper surface) 30B on a side opposite to the main surface 30A. The main surface 30B of the third substrate SUB3 is, for example, bonded to the main surface 10A of the insulating substrate 10 by an adhesive or the like.

The insulating substrates 10, 20, and 30 are substrates with an insulative characteristic and have flexibility. The insulating substrates 10, 20, and 30 are formed of, for example, film-like resin. The protective layers 11 and 21 are formed of inorganic insulating materials and are formed of, for example, SiOx films. The buffer layers 12 and 22 are formed of organic materials. The insulating layer 13 may be an inorganic insulating film or an organic insulating film. In addition, the insulating layer 13 may be a single layer or a multilayer film. The signal lines SL and the power supply lines CL are formed of, for example, metal lines.

The first electrode 31 and the second electrode 32 are formed of, for example, transparent conductive materials such as indium tin oxide (ITO) or indium zinc oxide (IZO).

The electron injection layer 14 is formed of a material having electron injection characteristics. A material generally used for electron injection layers can be employed as the electron injection layer 14.

The hole injection layer 16 is formed of a material having hole injection characteristics. A material generally used as hole injection layers can be employed as the hole injection layer 16.

The active layer 15 is formed of a material whose properties (for example, voltage-current characteristics and resistance value) change in response to incident light. For example, the active layer 15 has a bulk heterostructure in which a p-type organic semiconductor and an n-type organic semiconductor, which is an n-type fullerene derivative (PCBM), exist together. In addition, as the active layer 15, for example, fullerene (C60), phenyl C61-butyric acid methyl ester (PCBM), copper phthalocyanine (CuPc), fluorinated copper phthalocyanine (F16CuPc), 5,6,11,12-tetraphenyltetracene (rubrene), perylene derivative (PDI), and the like, which are low-molecular-weight organic materials, can be used.

The active layer 15 can be formed using these low-molecular-weight organic materials via a vapor deposition process (dry process). In this case, the active layer 15 may be, for example, a multilayer film of CuPC and F16CuPC, or a multilayer film of rubrene and C60. The active layer 15 can also be formed using a coating process (wet process). In this case, the active layer 15 may be formed using a material obtained by combining the above-described low-molecular-weight organic materials with polymeric organic materials. As the polymeric organic materials, for example, poly(3-hexylthiophene) (P3HT), F8-alt-benzothiadiazole (F8BT), and the like, can be used. The active layer 15 may be a film in which P3HT and PCBM are mixed or a film in which F8BT and PDI are mixed.

The sealing adhesive layer 17 is formed of an inorganic film such as a silicon nitride film or an aluminum oxide film, or a resin film such as acrylic.

The sealing adhesive layer 17 is not limited to a single layer, but may be a multilayer film of two or more layers in which the above-described inorganic films and resin films are combined.

The sensor 100 of the present embodiment shown in FIG. 3 and FIG. 4 is provided inside the ring-shaped housing 200 as shown in FIG. 2. An inner circumferential direction 200C of the housing 200 shown in FIG. 2 is aligned with the first direction X shown in FIG. 3. In the example shown in FIG. 2, the sensor 100 is provided inside the first housing 210 of the housing 200. The main surface 10A of the insulating substrate 10 faces the inner circumferential surface 210B of the first housing 210, and the main surface 10B of the insulating substrate 10 faces the outer circumferential surface 210A of the first housing 210. The sensor 100 is curved along the outer circumferential surface 210A of the first housing 210.

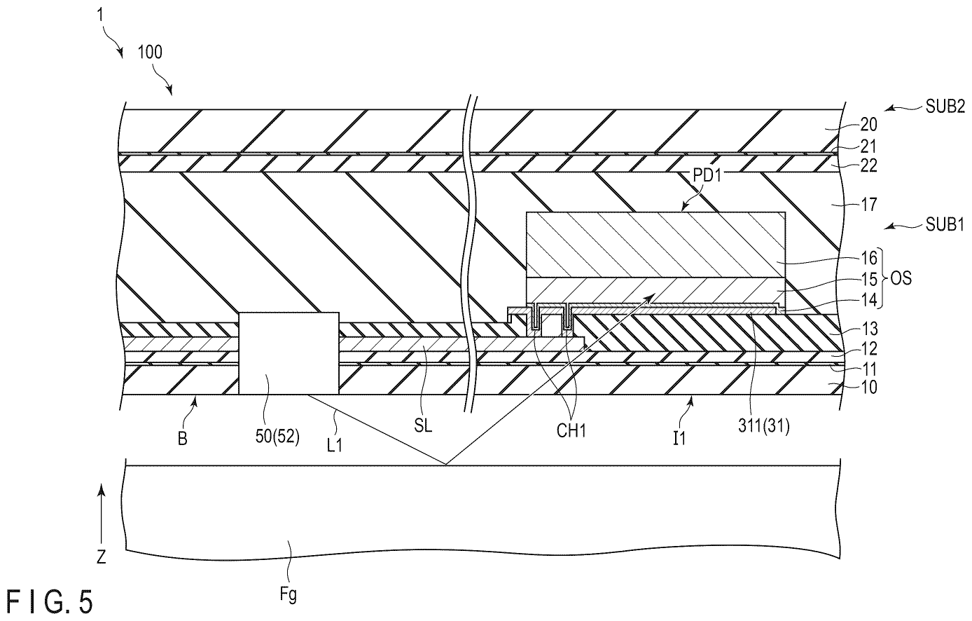

FIG. 5 is a cross-sectional view showing a configuration example of the detection device 1 shown in FIG. 2. As regards the detection device 1, only the sensor 100 is shown, and only the main part of the sensor 100 is shown. FIG. 5 shows an example in which the finger Fg is accommodated inside the detection device 1 as a detected object. The light emitted from the light source 50 will be described with reference to FIG. 5.

The light source 50 emits light L1 toward the detected object accommodated inside the detection device 1, for example, the finger Fg. The light L1 emitted from the light source is reflected on the surface or inside the finger Fg or transmitted through the finger Fg. In the example shown in FIG. 5, the light L1 is reflected on the surface of the finger Fg. The light L1 that is reflected on the finger Fg or passes through the finger Fg transmits through the insulating substrate 10 and is made incident on at least one of the first photodiode PD1 and the second photodiode PD2. Accordingly, the voltage-current characteristics and the resistance value of the active layer 15 change, and the current flows between the first electrode 31 and the second electrode 32 through the electron injection layer 14, the active layer 15, and the hole injection layer 16. The sensor 100 can detect the information on a living body of a detected body by detecting the current flowing between the first electrode 31 and the second electrode 32.

The information on the living body is, for example, fingerprints, pulse waves of fingers or palms, heartbeat, vascular images, blood oxygen saturation, and the like. Different information on the living body can be detected depending on the type of the light L1 emitted from the light source 50. For example, when the light L1 emitted from the light source 50 is green light, the heartbeat and the like of the detected object can be detected. In addition, when the light L1 emitted from the light source 50 is infrared light or red light, blood oxygen saturation, and the like, can be detected. For example, when the first light source 51 shown in FIG. 3 emits infrared light or red light and the second light source 52 and the third light source emit green light, it is sufficient to turn on at least one of the second light source 52 and the third light source to detect the pulse of the detected object, and it is sufficient to turn on only the first light source 51 to detect blood oxygen saturation.

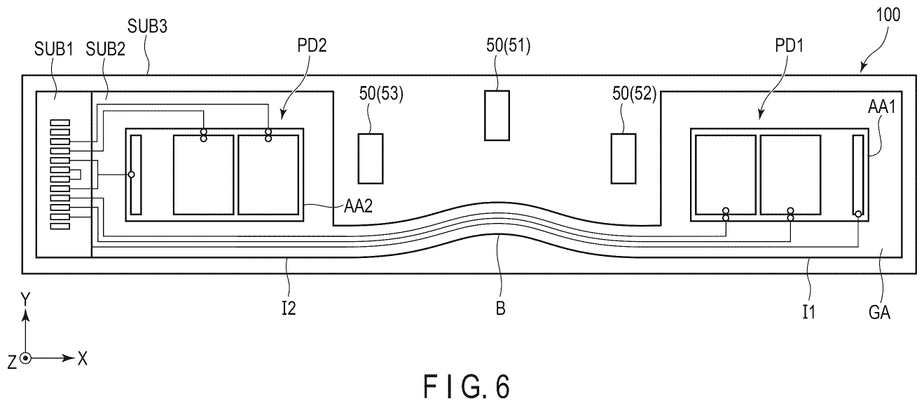

FIG. 6 is a plan view showing a state in which the band portion B of the sensor 100 shown in FIG. 3 extends in the first direction X.

As shown in FIG. 6, the curved portion extends in the first direction X, and the band portion B thereby extends in the first direction X. As a result, the sensor 100 extends in the first direction X.

When the sensor 100 comprises the third substrate SUB3, the third substrate SUB3 extends in the first direction X in response to the extension of the band portion B. The distance in the first direction X between the second light source 52 and the first island portion I1, and the distance in the first direction X between the third light source 53 and the second island portion I2, desirably do not change before and after the extension of the band portion B. This is to suppress the incident angle of the light L1, which is emitted from the second light source 52 and the third light source 53 and reflected on the finger Fg or the like when made incident on the photodiode PD, being changed depending on the degree of extension of the band portion B.

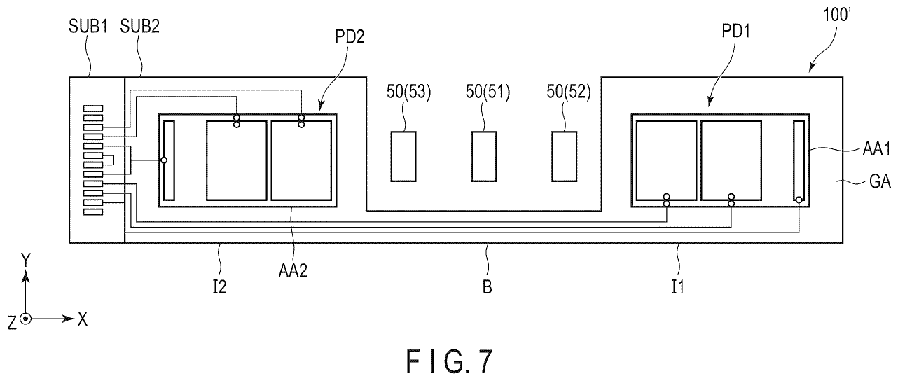

FIG. 7 is a plan view showing a sensor 100′ of a comparative example. The sensor 100′ is different from the sensor 100 of the present embodiment shown in FIG. 3 in that the band portion B is not curved.

The ring-shaped detection device 1 requires housings 200 of various sizes depending on the size of the detected object, for example, the finger Fg. At this time, the size in the first direction X of the sensor 100, which is provided inside the housing 200, also needs to be changed according to the size of the inner circumference of the housing 200. This is to unify the incident angle of the light L1 emitted from the light source 50 when made incident on the finger Fg or the like, the reflection angle when the light is reflected from the finger Fg or the like, the incident angle when the light is made incident on the photodiode PD, and the like, regardless of the size of the housing 200.

In the sensor 100′of the comparative example, the band portion B is not curved, and the band portion B does not extend in the first direction X. In other words, the size of the sensor 100′ in the first direction X does not change. For this reason, in order to unify the above-described angles regardless of the size of the housing 200, sensors 100′ of various sizes need to be formed depending on the size of the housing 200.

In contrast, in the sensor 100 of the present embodiment, the band portion B is curved, and the band portion B extends in the first direction X. Therefore, the size of the sensor 100 in the first direction X can be changed according to the size of the inner circumference of the housing 200. Thus, according to the present embodiment, the sensor 100 which can be applied to housings of various sizes can be provided.

Next, other configuration examples of the present embodiment will be described.

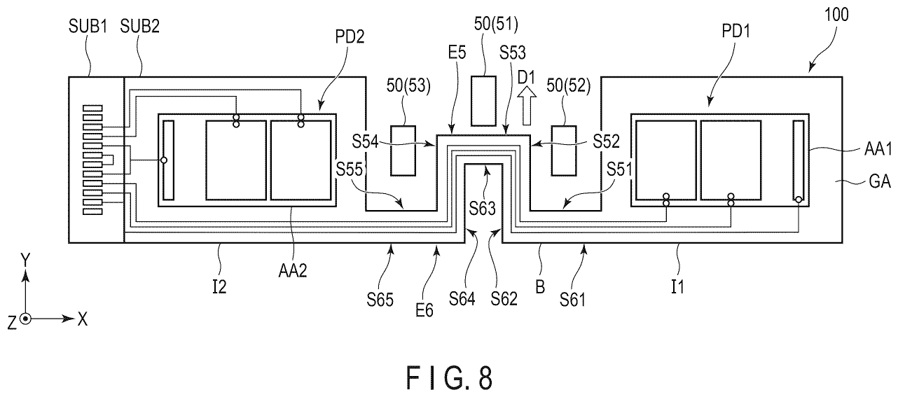

FIG. 8 is a plan view showing another configuration example of the sensor 100 shown in FIG. 3. The configuration example shown in FIG. 8 is different from the configuration example shown in FIG. 3 in that the edges E5 and E6 of the band portion B have straight edges in the curved portions.

In the example shown in FIG. 3, the edge E5 includes a straight portion S51 connected to the first island portion I1, a straight portion S52 connected to the straight portion S51, a straight portion S53 connected to the straight portion S52, a straight portion S54 connected to the straight portion S53, and a straight portion S55 connected to the straight portion S54. The straight portion S55 has one end connected to the straight portion S54 and the other end connected to the second island portion I2.

In the example shown in FIG. 8, the straight portions S51, S53, and S55 extend in the first direction X, but may extend in a direction different from the first direction X. In addition, in the example shown in FIG. 8, the straight portions S52 and S54 extend in the second direction Y, but may extend in a direction different from the second direction Y.

In the example shown in FIG. 8, the angle formed by the straight portions S51 and S52, the angle formed by the straight portions S52 and S53, the angle formed by the straight portions S53 and S54, and the angle formed by the straight portions S54 and S55 are approximately 90 degrees, but the angles are not limited to this example.

The edge E6 includes a straight portion S61 connected to the first island portion I1, a straight portion S62 connected to the straight portion S61, a straight portion S63 connected to the straight portion S62, a straight portion S64 connected to the straight portion S63, and a straight portion S65 connected to the straight portion S63. The straight portion S65 has one end connected to the straight portion S64 and the other end connected to the second island portion I2.

In the example shown in FIG. 8, the straight portions S61, S63, and S65 extend in the first direction X, but may extend in a direction different from the first direction X. In addition, in the example shown in FIG. 8, the straight portions S62 and S64 extend in the second direction Y, but may extend in a direction different from the second direction Y.

In the example shown in FIG. 8, the angle formed by the straight portions S61 and S62, the angle formed by the straight portions S62 and S63, the angle formed by the straight portions S63 and S64, and the angle formed by the straight portions S64 and S65 are approximately 90 degrees, but the angles are not limited to this example.

Even in such a configuration example, the same effects as those shown in the configuration example shown in FIG. 3 can be obtained.

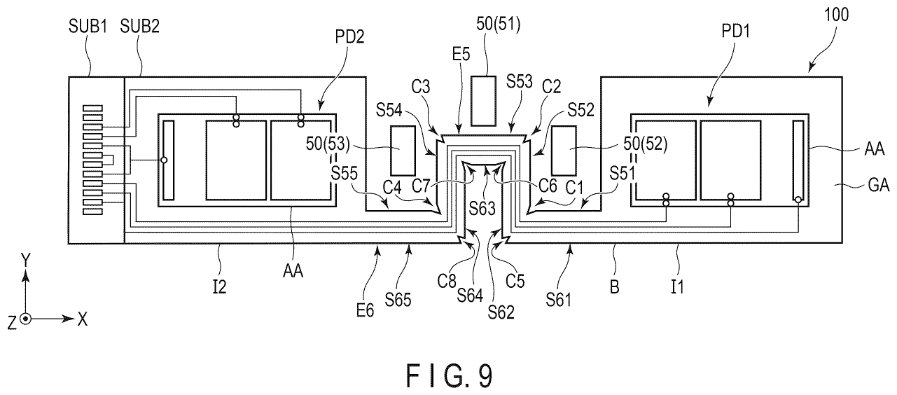

FIG. 9 is a plan view showing another configuration example of the sensor 100 shown in FIG. 8. The configuration example shown in FIG. 9 is different from the configuration example shown in FIG. 8 in that the band portion B has a notch portion.

In the example shown in FIG. 9, the band portion B has a notch portion C1 at the intersection of the straight portions S51 and S52, a notch portion C2 at the intersection of the straight portions S52 and S53, a notch portion C3 at the intersection of the straight portions S53 and S54, and a notch portion C4 at the intersection of the straight portions S54 and S55.

In the example shown in FIG. 9, the band portion B has a notch portion C5 at the intersection of the straight portions S61 and S62, a notch portion C6 at the intersection of the straight portions S62 and S63, a notch portion C7 at the intersection of the straight portions S63 and S64, and a notch portion C8 at the intersection of the straight portions S64 and S65.

The sensor 100 shown in FIG. 9 has notches at the intersections of the straight portions at the curved portions of the band portion B. It is therefore possible to suppress the band portion B breaking at the intersections of the straight portions by load applied to the intersections of the straight portions when the band portion B extends in the first direction X. In addition, even in such a configuration example, the same effects as those shown in the configuration example shown in FIG. 3 can be obtained.

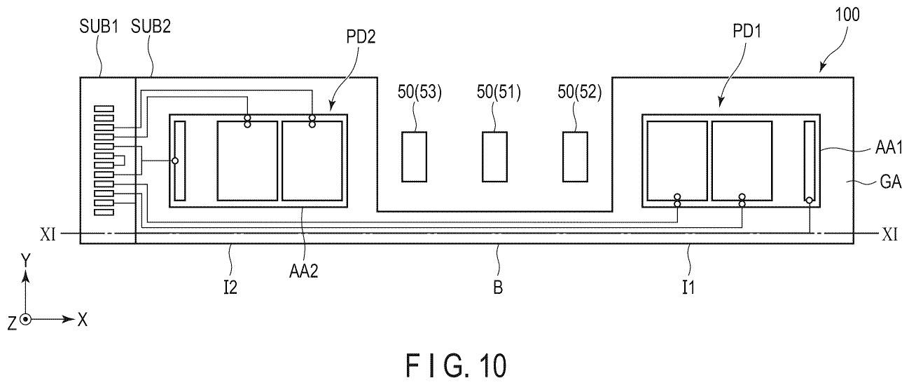

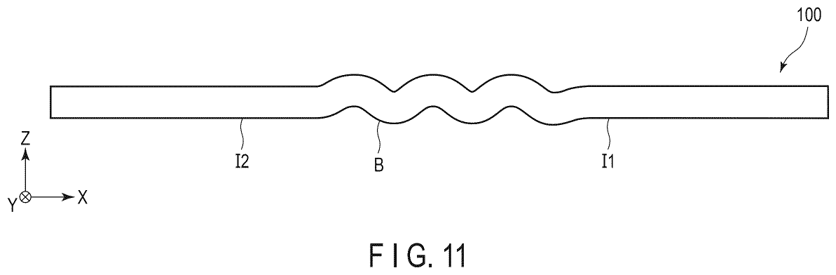

FIG. 10 is a plan view showing another configuration example of the sensor 100 shown in FIG. 3. In addition, FIG. 11 is a schematic cross-sectional view showing the sensor 100 along XI-XI line in FIG. 10. The configuration examples shown in FIG. 10 and FIG. 11 are different from the configuration example shown in FIG. 3 in that the band portion B is curved in a direction orthogonal to the insulating substrate 10. In addition, the first light source 51, the second light source 52, and the third light source 53 are arranged in the first direction X, and the first light source 51 does not protrude in the same direction as the protruding direction D1 of the band portion B, in the second direction Y, relative to the second light source 52 and the third light source 53.

As shown in FIG. 11, the band portion B protrudes to be curved in the third direction Z, i.e., a direction orthogonal to the insulating substrate 10. In the examples shown in FIG. 10 and FIG. 11, the band portion B comprises three portions protruding in the third direction Z, which is not particularly limited, but may comprise one or more portions protruding in the third direction Z. Even in such a configuration example, the same effects as those shown in the configuration example shown in FIG. 3 can be obtained.

As described above, according to the present embodiment, a sensor which can be applied to housings of various sizes can be provided.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is

1. A sensor comprising:
an insulating substrate including a first island portion and a second island portion arranged in a first direction, and a band portion provided between the first island portion and the second island portion to connect the first island portion with the second island portion;
an insulating layer provided above the insulating substrate;
a plurality of first electrodes provided on the insulating layer to overlap with each of the first island portion and the second island portion in plan view; and
a semiconductor layer provided on the plurality of first electrodes, wherein
the band portion is curved.

2. The sensor of claim 1, wherein
the band portion is curved in a plane parallel to the insulating substrate.

3. The sensor of claim 2, wherein
the band is curved by protruding in a second direction orthogonal to the first direction.

4. The sensor of claim 3, further comprising, in plan view:
a first light source provided between the first island portion and the second island portion;
a second light source provided between the first island portion and the first light source in the first direction; and
a third light source provided between the second island portion and the first light source in the first direction.

5. The sensor of claim 4, wherein
the first light source is provided to protrude in a direction in which the band portion protrudes, beyond the second light source and the third light source, in the second direction.

6. The sensor of claim 4, wherein
the first light source emits infrared light or red light.

7. The sensor of claim 4, wherein
the second light source and the third light source emit green light.

8. The sensor of claim 1, wherein
the band portion is curved in a plane orthogonal to the insulating substrate.

9. The sensor of claim 8, further comprising, in plan view:
a first light source provided between the first island portion and the second island portion;
a second light source provided between the first island portion and the first light source in the first direction; and
a third light source provided between the second island portion and the first light source in the first direction.

10. The sensor of claim 9, wherein
the first light source emits infrared light or red light.

11. The sensor of claim 9, wherein
the second light source and the third light source emit green light.

12. The sensor of claim 1, wherein
the band portion has a notch portion.

13. The sensor of claim 1, further comprising:
a plurality of terminals overlapping with the second island portion in plan view; and
signal lines electrically connecting the plurality of first electrodes overlapping with the first island portion with the plurality of terminals, in plan view, wherein
the signal lines overlap with the band portion in plan view.

14. The sensor of claim 1, wherein
the semiconductor layer includes an electron injection layer in contact with the first electrode, an active layer in contact with the electron injection layer, and a hole-injection layer in contact with the active layer.

15. The sensor of claim 14, further comprising:
a second electrode in contact with the hole-injection layer.

16. The sensor of claim 15, wherein
the first electrode and the second electrode are provided on the insulating layer.

17. The sensor of claim 1, wherein
the size in the first direction is changeable by extending the band portion in the first direction.

18. A detection device comprising:
a sensor; and
a ring-shaped housing, wherein
the sensor comprises
an insulating substrate including a first island portion and a second island portion arranged in a first direction, and a band portion provided between the first island portion and the second island portion to connect the first island portion with the second island portion,
an insulating layer provided above the insulating substrate,
a plurality of first electrodes provided on the insulating layer to overlap with each of the first island portion and the second island portion in plan view, and
a semiconductor layer provided on the plurality of first electrodes, wherein
the band portion is curved, and
the sensor is provided inside the housing.

19. A detection device comprising:
a sensor; and
a ring-shaped housing, wherein
the sensor comprises
an insulating substrate including a first island portion and a second island portion arranged in a first direction, and a band portion provided between the first island portion and the second island portion to connect the first island portion with the second island portion,
an insulating layer provided above the insulating substrate,
a plurality of first electrodes provided on the insulating layer to overlap with each of the first island portion and the second island portion in plan view,
a semiconductor layer provided on the plurality of first electrodes,
a first light source provided between the first island portion and the second island portion in plan view,
a second light source provided between the first island portion and the first light source in the first direction, and
a third light source provided between the second island portion and the first light source in the first direction, wherein
the band portion is curved, and
the sensor is provided inside the housing.

20. The detection device of claim 19, wherein
the sensor is capable of changing the size in the first direction by extending the band portion in the first direction.
